(19) United States
(12) Patent Application Publication
(10) Pub. No.: US 2009/0035696 A1
(43) Pub. Date: Feb. 5, 2009

(54) PHOTORESIST COMPOSITION

(75) Inventor: Hiroshi Matsuoka, Tokyo (JP)

Correspondence Address: FITZPATRICK CELLA HARPER & SCINTO, 30 ROCKEFELLER PLAZA, NEW YORK, NY, 10112, US

(73) Assignee: KYOWA HAKKO CHEMICAL CO., LTD., Chiyoda-ku, Tokyo (JP)

(21) Appl. No.: 11/913,331

(22) PCT Filed: May 17, 2006
(86) PCT No.: PCT/JP2006/309832

§ 371 Date: Nov. 1, 2007

(30) Foreign Application Priority Data
May 17, 2005 (JP) 2005-143375

(51) Int. Cl. G03C 1/73; C08G 67/00; G03F 7/20

(52) U.S. Cl. 430/281.1; 528/392; 430/325

(57) ABSTRACT

Disclosed are a photoresist composition characterized by containing a polymer (A) containing a carboxyl group or a hydroxyl group, a polyfunctional alkenyl ether (B) represented by the general formula (I) below, and a photoacid generator (C) and the like. (In the formula, R¹ and R² may be the same as or different from each other and respectively represent a substituted or unsubstituted alkyl, a substituted or unsubstituted allyl, or a substituted or unsubstituted aralkyl, or alternatively R¹ and R² may form a substituted or unsubstituted alicyclic hydrocarbon ring together with an adjacent carbon atom; X represents a substituted or unsubstituted alkane from which n hydrogen atoms are removed; and n represents an integer of not less than 2.)

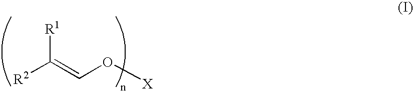

### TECHNICAL FIELD

The present invention relates to a photoresist composition useful in utilities such as manufacturing of a semiconductor, manufacturing of a liquid crystal panel, manufacturing of a flexible distributing plate, manufacturing of a printing plate and the like.

### BACKGROUND ART

A photoresist is a photosensitive material which forms a desired pattern by change in physical properties due to light exposure. Corresponding to dramatic miniaturization of a circuit pattern in electronic instruments such as a semiconductor, a liquid crystal panel and the like, also regarding a photoresist, many photoresists having a high sensitivity and a high resolution such as a chemical amplification-type photoresist have been proposed (e.g. see Patent Documents 1-3).

A mechanism of formation of a chemical amplification-type photoresist positive-type pattern is as follows. A composition containing a resin containing a hydroxyl group or a carboxyl group protected as an acetal or a tertiary ester, and a compound which is degraded with light to generate an acid (hereinafter, referred to as photoacid generator) is coated on a substrate, and is selectively exposed to light using a photomask or the like. At a light-exposed part, the photoacid generator is degraded to generate an acid. By heating the substrate, an acetal or a tertiary ester is degraded with the acid as a catalyst, to regenerate a hydroxyl group or a carboxyl group. The resin containing a regenerated hydroxyl group or carboxyl group is dissolved in an alkaline developer to obtain a positive-type pattern.

A key in pattern formation in this mechanism is a difference in solubility of the light-exposed part and the light-unexposed part in an alkaline developer. Therefore, when the light-unexposed part is not completely insoluble in a developer, there are defects that the light-unexposed part is also dissolved and swollen at development, and a resolution is reduced, and etching resistance of a pattern is reduced.

In order to improve these defects, there is proposed a method of heating a photoresist composition containing a resin containing a hydroxyl group or a carboxyl group, a divinyl ether compound, and a photoacid generator on a substrate to cross-link the resin, thereby, considerably reducing solubility of the light-unexposed part in an alkaline developer and, at the same time, elevating a glass transition temperature (Tg), and improving a resolution or etching resistance of a pattern (e.g. see Patent Documents 4-7).

In this method, an acetal linkage or a hemiacetal linkage produced by a reaction of a vinyl group in the divinyl ether compound and a hydroxyl group or a carboxyl group in the resin are extremely unstable to heat or an acid. Therefore, there were defects that a cross-linked structure of the light-unexposed part is degraded by slight slippage of a light exposure amount or the heating condition, a pattern is collapsed, and change in a dimension of a formed pattern is easily caused at development.

In addition, a divinyl ether compound itself, which is a cross-linking agent, is extremely easily polymerized by heating or the presence of an acid. Therefore, there was a defect that the resin is polymerized with an acid generated by heating or light exposure, and remains on a substrate as a scum which is not dissolved in an alkaline developer.

Further, there was a defect that a photoresist composition with a divinyl ether compound added thereto is deteriorated in storage stability, and a sensitivity, a resolution, a pattern shape and the like are different between at preparation of a resist composition and a few days after therefrom.

Patent Document 1: U.S. Pat. No. 4,491,628

### Patent Document 2: JP-A 59-45439

### Patent Document 3: JP-A 4-219757

### Patent Document 4: JP-A 6-148889

### Patent Document 5: JP-A 6-230574

### Patent Document 6: JP-A 6-295064

### Patent Document 7: JP-A 9-274320

### DISCLOSURE OF THE INVENTION

### Problems to be solved by the Invention

An object of the present invention is to provide a photoresist composition in which change in a pattern shape is small, and a scum is small and the like.

### Means to Solve the Problem

The present invention provides the following [1] to [6].

[1] A photoresist composition comprising (A) a polymer containing a carboxyl group or a hydroxyl group, (B) a polyfunctional alkenyl ether represented by the general formula (I):

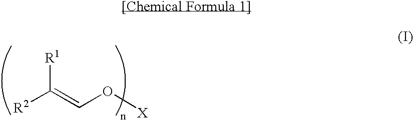

[wherein R¹ and R² may be the same as or different from each other and, respectively, represent substituted or unsubstituted alkyl, substituted or unsubstituted aryl or substituted or unsubstituted aralkyl, or R¹ and R² may form a substituted or unsubstituted alicyclic hydrocarbon ring together with a carbon atom adjacent thereto, X represents a substituted or unsubstituted alkane from which hydrogen atoms in the number of n are removed (the alkane includes alkane substituted with 1 to 2 aryls, and a part of carbon atoms of the alkane may be substituted with an oxygen atom or SO₂), a substituted or unsubstituted aromatic ring from which hydrogen atoms in the number of n are removed (the aromatic ring includes an aromatic ring substituted with alkyl), or a group represented by —{(CH₂—CH₂—O)ₘ—CH₂—CH₂}— (wherein m represents an integer of not less than 1) from which hydrogen atoms in the number of (n−2) are removed, and n represents an integer of not less than 2],
and (C) a photoacid generator.

[2] The photoresist composition according to [1], wherein the (A) polymer comprises a repetition unit represented by the general formula (II):

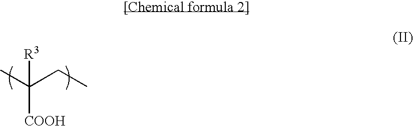

(wherein R³ represents a hydrogen atom or methyl), and has a weight average molecular weight of 1,000-10,000.

[3] The photoresist composition according to [1], wherein the (A) polymer comprises a repetition unit represented by the general formula (III):

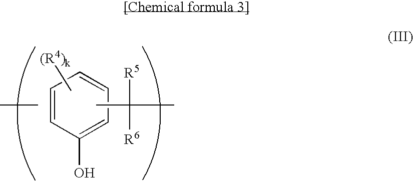

(wherein R⁴ represents a hydrogen atom, substituted or unsubstituted alkyl, substituted or unsubstituted aryl or substituted or unsubstituted aralkyl, k represents an integer of 1 to 3, R⁵ and R⁶ may be the same as or different from each other and, respectively, represent a hydrogen atom, substituted or unsubstituted alkyl, substituted or unsubstituted aryl or substituted or unsubstituted aralkyl), and has a weight average molecular weight of 1,000 to 100,000.

[4] The photoresist composition according to [1], wherein the (A) polymer comprises a repetition unit represented by a general formula (IV);

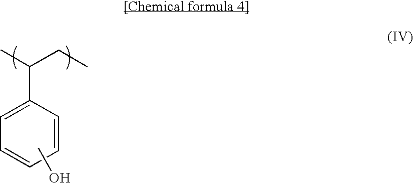

and has a weight average molecular weight of 1,000 to 100,000.

[5] A method of forming a pattern comprising a step of coating the photoresist composition as defined in any one of [1] to [4] on a substrate, a step of heating the substrate, a step of exposing a coated film on the substrate to radiation, a step of heating the substrate after exposure, and a step of developing the substrate using an alkaline developer.

[6] A polyfunctional alkenyl ether represented by the general formula (V):

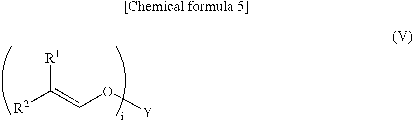

[wherein R¹ and R² are as defined above, Y represents a substituted or unsubstituted alkane from which hydrogen atoms in the number of i are removed (the alkane includes alkane substituted with 1 to 2 aryls, and a part of carbon atoms of the alkane may be substituted with an oxygen atoms or SO₂), a substituted or unsubstituted aromatic ring from which hydrogen atoms in the number of i are removed (the aromatic ring includes an aromatic ring substituted with alkyl), or a group represented by —{(CH₂—CH₂—O)ₘ—CH₂—CH₂}— (wherein m is as defined above) from which hydrogen atoms in the number of (i−2) are removed, and i represents an integer of 2 to 4].

Hereafter, the polyfunctional alkenyl ether represented by the general formula (I) is expressed as Compound I in some cases. Other formula numbers are expressed similarly in some cases.

In addition, the polymer containing a carboxyl group or a hydroxyl group is expressed as Polymer (A) in some cases.

### EFFECT OF THE INVENTION

According to the present invention, a photoresist composition in which change in a pattern shape is small and a scum is small and the like can be provided.

### BEST MODE FOR CARRYING OUT THE INVENTION

In definition of each group in the general formula, examples of the alkyl includes a straight or branched alkyl of a carbon number of 1 to 18, specifically, methyl, ethyl, propyl, isopropyl, butyl, isobutyl, sec-butyl, tert-butyl, pentyl, hexyl, heptyl, octyl, nonyl, decyl, dodecyl, octadecyl and the like. Among them, an alkyl of a carbon number of 1 to 6 is preferable, and an alkyl of a carbon number of 1 to 3 is more preferable.

Examples of the aryl includes an aryl of a carbon number of 6 to 14, specifically, phenyl, naphthyl and the like.

Examples of the aralkyl includes an aralkyl of a carbon number of 7 to 15, specifically, benzyl, phenethyl, naphthylmethyl, naphthylethyl and the like.

Examples of the alkane includes a straight or branched alkane of a carbon number of 1 to 18, a cyclic alkane of a carbon number of 3 to 18, and a combination thereof, specifically, methane, ethane, propane, butane, pentane, hexane, heptane, octane, nonane, decane, dodecane, octadecane, cyclopropane, cyclobutane, cyclopentane, cyclohexane, cycloheptane, cyclooctane, cyclononane, cyclodecane, cyclododecane, dimethylcyclohexane, tricyclodecane, methyltricyclodecane, adamantane, tetracyclododecane, bornane, norbornane, isonorbornane, spiroheptane, spirooctane, menthane and the like.

Examples of the aryl in the alkane from which n or i hydrogen atoms are removed, which is substituted with 1 to 2 aryls, include the same aryls as those described above.

Examples of the aromatic ring include an aromatic ring of a carbon number of 6 to 14, specifically, benzene, naphthalene and the like.

Examples of the alkyl in the aromatic ring from which n or i hydrogen atoms are removed, which is substituted with alkyl, include the same alkyls as those described above.

Examples of the alicyclic hydrocarbon ring formed by R¹ and R² together with an adjacent carbon atom include an alicyclic hydrocarbon ring of a carbon number of 3 to 8, which may be saturated or unsaturated, specifically, a cyclopropane ring, a cyclobutane ring, a cyclopentane ring, a cyclohexane ring, a cycloheptane ring, a cyclooctane ring, a cyclopentene ring, a 1,3-cyclopentadiene ring, a cyclohexene ring, a cyclohexadiene ring and the like.

Examples of a substituent in the substituted alkyl and the substituted alkane include alkoxy, alkanoyl, cyano, nitro, halogen atom, alkoxycarbonyl and the like.

Examples of a substituent in the substituted aryl, the substituted aralkyl, the substituted aromatic ring and the substituted alicyclic hydrocarbon ring formed by R¹ and R² together with an adjacent carbon atom include alkyl, alkoxy, alkanoyl, cyano, nitro, halogen atom, alkoxycarbonyl and the like.

In definition of the substituent, examples of the alkyl, and an alkyl part of the alkoxy and the alkoxycarbonyl include the same alkyls as those listed above for the alkyl. Examples of the alkanoyl include a straight or branched alkanoyl of a carbon number of 2 to 7, specifically, acetyl, propionyl, butyryl, isobutyryl, valeryl, isovaleryl, pivaloyl, hexanoyl, heptanoyl and the like. Examples of the halogen atom include respective atoms of fluorine, chlorine, bromine and iodine and, inter alia, a chlorine atom is preferable.

In the polyfunctional alkenyl ether represented by the general formula (I), it is preferable that n is 2 to 4, X is a group represented by —{(CH₂—CH₂—O)ₘ—CH₂—CH₂}— from which n−2 hydrogen atoms are removed, and m is 1 to 10, and it is more preferable that n is 2, X is a group represented by —{(CH₂—CH₂—O)ₘ—CH₂—CH₂}— from which (n−2) hydrogen atoms are removed, and m is 1 to 4.

In the polyfunctional alkenyl ether represented by the general formula (V), it is preferable that Y is a group represented by —{(CH₂—CH₂—O)ₙ—CH₂—CH₂}— from which (n−2) hydrogen atoms are removed, and m is 1 to 10, and it is more preferable that Y is a group represented by —{(CH₂—CH₂—O)ₘ—CH₂—CH₂}— from which (n−2) hydrogen atoms are removed, and m is 1 to 4.

### (A) Polymer Containing Carboxyl Group or Hydroxyl Group

Examples of the polymer containing a carboxyl group include polymers such as a carboxyl group-containing polyester resin, an alkyd resin, a urethane resin, a polyamic acid resin, an epoxy resin, a carboxyl group-modified epoxy resin and the like, homopolymers such as a polymerizable unsaturated monomer containing a carboxylic group, copolymers of a polymerizable unsaturated monomer containing a carboxyl group and other monomer copolymerizable therewith and the like and, among them, a homopolymer such as a polymerizable unsaturated monomer containing a carboxyl group, or a copolymer of a polymerizable unsaturated monomer containing a carboxyl group and other monomer copolymerizable therewith is preferable.

Examples of the polymerizable unsaturated monomer containing a carboxyl group include unsaturated carboxylic acids or anhydrides thereof such as (meth)acrylic acid, maleic acid, itaconic acid, maleic acid anhydride, itaconic acid anhydride and the like and, among them, (meth)acrylic acid is preferable. Herein, (meth)acrylic acid represents acrylic acid and methacrylic acid, and this also applies to other (meth)acrylic acid derivative.

Examples of the copolymerizable other monomer include alkyl(meth)acrylates obtained by using, as a raw material, an alcohol of a carbon number of 1 to 18 and (meth)acrylic acid such as methyl(meth)acrylate, ethyl(meth)acrylate, propyl(meth)acrylate, butyl(meth)acrylate, isobutyl (meth)acrylate, tert-butyl(meth)acrylate, 2-ethylhexyl (meth)acrylate, lauryl(meth)acrylate, stearyl (meth)acrylate and the like, (meth)acrylates such as cyclohexyl(meth)acrylate, benzyl(meth)acrylate, isobornyl (meth)acrylate, adamantyl(meth)acrylate and the like, hydroxyalkyl(meth)acrylates such as 2-hydroxyethyl (meth)acrylate, 2-hydroxypropyl(meth)acrylate, monoglycerol (meth)acrylate and the like, glycol di(meth)acrylates such as ethylene glycol di(meth)acrylate, butanediol di(meth)acrylate and the like, nitrogen-containing monomers such as (meth)acrylamide, (meth)acrylonitrile, diacetone(meth)acrylamide, dimethylaminoethyl(meth)acrylate and the like, fluorine-containing vinyl-based monomers such as trifluoroethyl (meth)acrylate, pentafluoropropyl(meth)acrylate, perfluorocyclohexyl(meth)acrylate and the like, epoxy group-containing monomers such as allyl glycidyl ether, glycidyl(meth)acrylate and the like, styrene-based monomers such as styrene, α-methylstyrene, p-methylstyrene, dimethylstyrene, divinylbenzene and the like, vinyl ethers such as vinyl methyl ether, vinyl ethyl ether, vinyl isobutyl ether and the like, polybasic unsaturated carboxylic acids such as fumaric acid, maleic acid, maleic acid anhydride and the like, or monohydric or polyhydric alcohol esters of them, allyl alcohol, allyl alcohol ester, vinyl chloride, vinylidene chloride, trimethylolpropane tri(meth)acrylate, vinyl acetate, vinyl propionate and the like. These monomers may be used alone, or may be used by combining two or more kinds.

Polymerization of the polymerizable unsaturated monomer containing a carboxyl group, and copolymerization of the polymerizable unsaturated monomer containing a carboxyl group and other monomer copolymerizable therewith can be performed by the known method.

Alternatively, as the polymer containing a carboxyl group, a commercially available resin may be also used.

A proportion of a carboxyl group in the polymer containing a carboxyl group is not particularly limited, but is preferably 20 to 200, more preferably 40 to 160 as expressed by an acid value. Herein, the acid value is a mg number of potassium hydroxide necessary for neutralizing a carboxyl group contained in 1 g of the polymer.

A weight average molecular weight of the polymer containing a carboxyl group is preferably 1,000 to 100,000, more preferably 3,000 to 50,000, further preferably 3,000 to 30,000.

Examples of the polymer containing a hydroxyl group include copolymers obtained by copolymerizing novolak resin, polyhydroxystyrene, or hydroxystyrene and other monomer copolymerizable therewith, and the like.

The novolak resin is obtained by polycondensation of phenols such as m-cresol, p-cresol, 2,3-xylenol, 2,4-xylenol, 2,5-xylenol, 2,6-xylenol, 3,4-xylenol, 3,5-xylenol, 2,3,4-trimethylphenol, 2,3,5-trimethylphenol, 3,4,5-trimethylphenol and the like alone, or a mixture thereof, and aldehydes such as formaldehyde, benzaldehyde, furfural, acetoaldehyde and the like in the presence of an acidic catalyst. These phenols and aldehydes can be used alone, or by combining two or more kinds. Upon polycondensation, a proportion of m-cresol, p-cresol and phenols to be used is preferably 40 to 95/0 to 60/0 to 50 as expressed by a mole ratio of m-cresol/p-cresol/phenols. And, a proportion of aldehyde to be used is preferably 0.7 to 3 mole, more preferably 0.75 to 1.73 mole based on a total amount of 1 mole of m-cresol, p-cresol and phenols.

Examples of other monomer copolymerizable with hydroxystyrene include the polymerizable unsaturated monomer containing a carboxyl group and other monomer copolymerizable therewith. These monomers may be used alone, or may be used by combning two or more kinds.

Polymerization of hydroxystyrene, and copolymerization of hydroxystyrene and other monomer copolymerizable therewith can be performed by the known method.

A proportion of hydroxystyrene in a copolymer in which hydroxystyrene is copolymerized with other monomer copolymerizable therewith is not particularly limited, but is preferably 0.2 to 90 mole %, more preferably 0.2 to 60 mole %.

Alternatively, as the polymer containing a hydroxyl group, a commercially available resin may be also used.

A weight average molecular weight of the polymer containing a hydroxyl group is preferably 500 to 100,000, more preferably 1,000 to 50,000, further preferably 1,000 to 20,000.

The polymer containing a carboxyl group or a hydroxyl group may be purified, and used as a solid. When a solvent is used upon production, the polymer may be also used as a solution.

### (B) Polyfunctional Alkenyl Ether

Examples of the polyfunctional alkenyl ether represented by the general formula (I) include ethylene glycol diisobutenyl ether, diethylene glycol diisobutenyl ether, triethylene glycol diisobutenyl ether, tetraethylene glycol diisobutenyl ether, polyethylene glycol diisobutenyl ether, 1,2-propylene glycol diisobutenyl ether, 1,3-propylene glycol diisobutenyl ether, 1,3-butanediol diisobutenyl ether, 1,4-butanediol diisobutenyl ether, 1,5-pentanediol diisobutenyl ether, 1,6-hexanediol diisobutenyl ether, 1,8-octanediol diisobutenyl ether, 1,9-nonanediol diisobutenyl ether, dodecanediol diisobutenyl ether, 2-methyl-1,3-propanediol diisobutenyl ether, 2-methyl-1,4-butanediol diisobutenyl ether, neopentyl glycol diisobutenyl ether, 3-methyl-1,5-pentanediol diisobutenyl ether, 2,4-diethyl-1,5-pentanediol diisobutenyl ether, 2-butyl2-ethyl-1,3-propanediol diisobutenyl ether, 2,2-diethyl-1,3-propanediol diisobutenyl ether, 2-ethyl-1,3-hexanediol diisobutenyl ether, cyclohexanedimethanol diisobutenyl ether, tricyclodecanedimethanol diisobutenyl ether, hydrogenated bisphenol A diisobutenyl ether, trimethylolpropane triisobutenyl ether, pentaerythritol tetraisobutenyl ether, dipentaerythritol hexaisobutenyl ether, glycerin triisobutenyl ether, resorcinol diisobutenyl ether, hydroquinone diisobutenyl ether, pyrocatechol diisobutenyl ether, bisphenol A diisobutenyl ether, bisphenol F diisobutenyl ether, bisphenol S diisobutenyl ether, ethylene glycol bis(2-ethyl-1-butenyl)ether, diethylene glycol bis(2-ethyl-1-butenyl)ether, triethylene glycol bis(2-ethyl-1-butenyl)ether, tetraethylene glycol bis(2-ethyl-1-butenyl)ether, polyethylene glycol bis(2-ethyl-1-butenyl)ether, 1,2-propylene glycol bis(2-ethyl-1-butenyl)ether, 1,3-propylene glycol bis(2-ethyl-1-butenyl)ether, 1,3-butanediol bis(2-ethyl-1-butenyl)ether, 1,4-butanediol bis(2-ethyl-1-butenyl)ether, 1,5-pentanediol bis(2-ethyl-1-butenyl)ether, 1,6-hexanediol bis(2-ethyl-1-butenyl)ether, 1,8-octanediol bis(2-ethyl-1-butenyl)ether, 1,9-nonanediol bis(2-ethyl-1-butenyl)ether, dodecanediol bis(2-ethyl-1-butenyl)ether, 2-methyl-1,3-propanediol bis(2-ethyl-1-butenyl)ether, 2-methyl-1,4-butanediol bis(2-ethyl-1-butenyl)ether, neopentyl glycol bis(2-ethyl-1-butenyl)ether, 3-methyl-1,5-pentanediol bis(2-ethyl-1-butenyl)ether, 2,4-diethyl-1,5-pentanediol bis(2-ethyl-1-butenyl)ether, 2-butyl-2-ethyl-1,3-propanediol bis(2-ethyl-1-butenyl)ether, 2,2-diethyl-1,3-propanediol bis(2-ethyl-1-butenyl)ether, 2-ethyl-1,3-hexanediol bis(2-ethyl-1-butenyl)ether, cyclohexanedimethanol bis(2-ethyl-1-butenyl)ether, tricyclodecanedimethanol bis(2-ethyl-1-butenyl)ether, hydrogenated bisphenol A bis(2-ethyl-1-butenyl)ether, trimethylolpropane tris(2-ethyl-1-butenyl)ether, pentaerythritol tetrakis(2-ethyl-1-butenyl)ether, dipentaerythritol hexakis(2-ethyl-1-butenyl)ether, glycerin tris(2-ethyl-1-butenyl)ether, resorcinol bis(2-ethyl-1-butenyl)ether, hydroquinone bis(2-ethyl-1-butenyl)ether, pyrocatechol bis(2-ethyl-1-butenyl)ether, bisphenol A bis(2-ethyl-1-butenyl)ether, bisphenol F bis(2-ethyl-1-butenyl)ether, bisphenol S bis(2-ethyl-1-butenyl)ether, ethylene glycol bis(2-ethyl-1-hexenyl)ether, diethylene glycol bis(2-ethyl-1-hexenyl)ether, triethylene glycol bis(2-ethyl-1-hexenyl)ether, tetraethylene glycol bis(2-ethyl-1-hexenyl)ether, polyethylene glycol his(2-ethyl-1-hexenyl)ether, 1,2-propylene glycol bis(2-ethyl-1-hexenyl)ether, 1,3-propylene glycol bis(2-ethyl-1-hexenyl)ether, 1,3-butanediol bis(2-ethyl-1-hexenyl)ether, 1,4-butanediol bis(2-ethyl-1-hexenyl)ether, 1,5-pentanediol bis(2-ethyl-1-hexenyl)ether, 1,6-hexanediol bis(2-ethyl-1-hexenyl)ether, 1,8-octanediol bis(2-ethyl-1-hexenyl)ether, 1,9-nonanediol bis(2-ethyl-1-hexenyl)ether, dodecanediol bis(2-ethyl-1-hexenyl)ether, 2-methyl-1,3-propanediol bis(2-ethyl-1-hexenyl)ether, 2-methyl-1,4-butanediol bis(2-ethyl-1-hexenyl)ether, neopentyl glycol bis(2-ethyl-1-hexenyl)ether, 3-methyl-1,5-pentanediol bis(2-ethyl-1-hexenyl)ether, 2,4-diethyl-1,5-pentanediol bis(2-ethyl-1-hexenyl)ether, 2-butyl-2-ethyl-1,3-propanediol bis(2-ethyl-1-hexenyl)ether, 2,2-diethyl-1,3-propanediol bis(2-ethyl-1-hexenyl)ether, 2-ethyl-1,3-hexanediol bis(2-ethyl-1-hexenyl)ether, cyclohexanedimethanol bis(2-ethyl-1-hexenyl)ether, tricyclodecanedimethanol bis(2-ethyl-1-hexenyl)ether, hydrogenated bisphenol A bis(2-ethyl-1-hexenyl)ether, trimethylolpropane tris(2-ethyl-1-hexenyl)ether, pentaerythritol tetrakis(2-ethyl-1-hexenyl)ether, dipentaerythritol hexakis(2-ethyl-1-hexenyl)ether, glycerin tris(2-ethyl-1-hexenyl)ether, resorcinol bis(2-ethyl-1-hexenyl)ether, hydroquinone bis(2-ethyl-1-hexenyl)ether, pyrocatechol bis(2-ethyl-1-hexenyl)ether, bisphenol A bis(2-ethyl-1-hexenyl)ether, bisphenol F bis(2-ethyl-1-hexenyl)ether, bisphenol S bis(2-ethyl-1-hexenyl)ether, ethylene glycol dicyclohexylidenyl ether, diethylene glycol dicyclohexylidenyl ether, triethylene glycol dicyclohexylidenyl ether, -etraethylene glycol dicyclohexylidenyl ether, polyethylene glycol dicyclohexylidenyl ether, 1,2-propylene glycol dicyclohexylidenyl ether, 1,3-propylene glycol dicyclohexylidenyl ether, 1,3-butanediol dicyclohexylidenyl ether, 1,4-butanediol dicyclohexylidenyl ether, 1,5-pentanediol dicyclohexylidenyl ether, 1,6-hexanediol dicyclohexylidenyl ether, 1,8-octanediol dicyclohexylidenyl ether, 1,9-nonanediol dicyclohexylidenyl ether, dodecanediol dicyclohexylidenyl ether, 2-methyl-1,3-propanediol dicyclohexylidenyl ether, 2-methyl-1,4-butanediol dicyclohexylidenyl ether, neopentylglycol dicyclohexylidenyl ether, 3-methyl-1,5-pentanediol dicyclohexylidenyl ether, 2,4-diethyl-1,5-pentane dioldicyclohexylidenyl ether, 2-butyl-2-ethyl-1,3-propanediol dicyclohexylidenyl ether, 2,2-diethyl-1,3-propanediol dicyclohexylidenyl ether, 2-ethyl-1,3-hexanediol dicyclohexylidenyl ether, cyclohexanedimethanol dicyclohexylidenyl ether, tricyclodecanedimethanol dicyclohexylidenyl ether, hydrogenated bisphenol A dicyclohexylidenyl ether, trimethylolpropane tricyclohexylidenyl ether, pentaerythritolte tracyclohexylidenyl ether, dipentaerythritol hexacyclohexylidenyl ether, glycerin tricyclohexylidenyl ether, resorcinol dicyclohexylidenyl ether, hydroquinone dicyclohexylidenyl ether, pyrocatechol dicyclohexylidenyl ether, bisphenol A dicyclohexylidenyl ether, bisphenol F dicyclohexylidenyl ether, bisphenol S dicyclohexylidenyl ether and the like, among them, diisobutenyl ether compounds such as ethylene glycol diisobutenyl ether, diethylene glycol diisobutenyl ether, triethylene glycol diisobutenyl ether, tetraethylene glycol diisobutenyl ether, polyethylene glycol diisobutenyl ether, 1,2-propylene glycol diisobutenyl ether, 1,3-propylene glycol diisobutenyl ether, 1,3-butanediol diisobutenyl ether, 1,4-butanediol diisobutenyl ether, 1,5-pentanediol diisobutenyl ether, 1,6-hexanediol diisobutenyl ether, 1,8-octanediol diisobutenyl ether, 1,9-nonanediol diisobutenyl ether, dodecanediol diisobutenyl ether, 2-methyl-1,3-propanediol diisobutenyl ether, 2-methyl-1,4-butanediol diisobutenyl ether, neopentylglycol diisobutenyl ether, 3-methyl-1,5-pentanediol diisobutenyl ether, 2,4-diethyl-1,5-pentanediol diisobutenyl ether, 2-butyl-2-ethyl-1,3-propanediol diisobutenyl ether, 2,2-diethyl-1,3-propanediol diisobutenyl ether, 2-ethyl-1,3-hexanedioldiisobutenyl ether, cyclohexanedimethanol diisobutenyl ether, tricyclodecanedimethanol diisobutenyl ether, hydrogenated bisphenol A diisobutenyl ether, trimethylolpropane triisobutenyl ether, pentaerythritol tetraisobutenyl ether, dipentaerythritol hexaisobutenyl ether, glycerin triisobutenyl ether, resorcinol diisobutenyl ether, hydroquinone diisobutenyl ether, pyrocatechol diisobutenyl ether, bisphenol A diisobutenyl ether, bisphenol F diisobutenyl ether, bisphenol S diisobutenyl ether and the like are preferable and, 1,4-butanediol diisobutenyl ether, ethylene glycol diisobutenyl ether, diethylene glycol diisobutenyl ether or cyclohexanedimethanol diisobutenyl ether is more preferable. Compounds (I) may be used alone, or by mixing two or more kinds.

An amount of the polyfunctional alkenyl ether represented by the general formula (I) in the photoresist composition of the present invention is not particularly limited, but is preferably 0.1 to 200 parts by weight, more preferably 1 to 100 parts by weight, further preferably 2 to 50 parts by weights based on 100 to parts by weight of the polymer containing a carboxyl group or a hydroxyl group.

The polyfunctional alkenyl ether represented by the general formula (I) can be produced, for example, by a step (1) of reacting a compound represented by the general formula (VI):

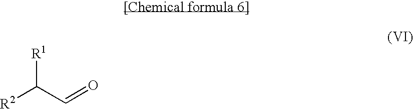

(wherein R¹ and R² are as defined above), a compound represented by the general formula (VII):

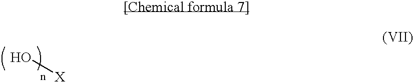

(wherein n and X are as defined above), and hydrogen halide to obtain α-haloether, and

a step (2) of eliminating hydrogen halide with the α-haloether in the presence of a base.

Examples of the compound represented by the general formula (VI) include isobutylaldehyde, 2-ethylbutylaldehyde, 2-ethylhexylaldehyde, cyclohexylaldehyde and the like.

Examples of the compound represented by the general formula (VII) include difunctional alcohols such as ethylene glycol, diethylene glycol, triethylene glycol, tetraethylene glycol, polyethylene glycol, 1,2-propylene glycol, 1,3-propylene glycol, 1,3-butanediol, 1,4-butanediol, 1,5-pentanediol, 1,6-hexanediol, 1,8-octanediol, 1,9-nonanediol, dodecanediol, 2-methyl-1,3-propanediol, 2-methyl-1,4-butanediol, neopentyl glycol, 3-methyl-1,5-pentanediol, 2,4-diethyl-1,5-pentanediol, 2-butyl-2-ethyl-1,3-propanediol, 2,2-diethyl-1,3-propanediol, 2-ethyl-1,3-hexanediol, cyclohexanedimethanol, tricyclodecanedimethanol, hydrogenated bisphenol A and the like, polyfunctional alcohols such as trimethylolpropane, pentaerythritol, dipentaerythritol, glycerin and the like, and phenol compounds such as resorcinol, hydroquinone, pyrocatechol, bisphenol A, bisphenol F, bisphenol S and the like.

Examples of the hydrogen halide include hydrogen chloride, hydrogen bromide, hydrogen iodide and the like and, among them, hydrogen chloride is preferable. Hydrogen halide can be used as a gas or an aqueous solution, and a gas is preferable.

In the step (1), a reaction proceeds by the presence of hydrogen halide in a mixture of the compound represented by the general formula (VI) and the compound represented by the general formula (VII). By removing water produced as a byproduct, the crude α-haloether product is obtained. Produced water may be removed by separating layers while the reaction solution is circulated to the outside of the system during a reaction, or may be removed by separating layers after completion of the reaction. Alternatively, dehydration may be performed using the known dehydrating agent such as molecular sieves, sodium sulfate and the like.

In addition, in the step (I), if necessary, nitrogen may be blown into the system.

An amount of the compound represented by the general formula (VI) to be used is preferably 1 to 10 mole, further preferably 1 to 5 mole, more preferably 1 to 2 mole based on 1 mole of a hydroxyl group in the compound represented by the general formula (VII).

An amount of hydrogen halide to be used is preferably not less than 1 mole based on 1 mole of a hydroxyl group in the compound represented by the general formula (VII).

A reaction temperature is not particularly limited, but is preferably 0 to 20° C.

In addition, in the step (1), a reaction solvent may be used as necessary. Examples of the reaction solvent include hydrocarbon-based solvents such as heptane, hexane, octane, dodecane, toluene, xylene and the like, ether-based solvents such as diethyl ether, diisopropyl ether, dibutyl ether, dioxane, tetrahydrofuran and the like, and ester-based solvents such as ethyl acetate, butyl acetate, isobutyl acetate and the like. Two or more kinds of these reaction solvents may be used simultaneously.

In the step (2), a reaction proceeds, for example, by adding a base to the crude product obtained in the step (1) and, if necessary, heating the mixture.

Examples of the base include tertiary amines such as trimethylamine, triethylamine, tripropylamine, triisopropylamine, tributylamine, triallylamine, tri-n-octylamine, tri(2-ethylhexyl)amine, tricyclohexylamine, tribenzylamine, N,N-dimethylethylamine, N,N-dimethylpropylamine, N,N-dimethylisopropylamine, N,N-dimethylbutylamine, N,N-di-methylallylamine, N,N-dimethyloctylamine, N,N-dimethyl(2-ethylhexyl)amine, N,N-dimethylcyclohexylamine, N,N-dimethylbenzylamine, N-methyldiethylamine, N-methyldipropylamine, N-methyldiisopropylamine, N-methyldibutylamine, N-methyldiallylamine, N-methyldioctylamine, N-methylbis(2-ethylhexyl)amine, N,N-diethylpropylamine, N,N-diethylisopropylamine, N,N-diethylbutylamine, N,N-diethylallylamine, N,N-diethyloctylamine, N,N-diethyl(2-ethylhexyl)amine, N,N-diethylcyclohexylamine, N-ethyldipropylamine, N-ethyldiisopropylamine, N-ethyldibutylamine, N-ethyldiallylamine, N-ethyldioctylamine, N-ethylbis(2-ethylhexyl)amine, N,N-dipropylisopropylamine, N,N-dipropylbutylamine, N,N-dipropylallylamine, N,N-dipropyloctylamine, N,N-dipropyl(2-ethylhexyl)amine, N,N-dipropylcyclohexylamine, N-propyldiisopropylamine, N-propyldibutylamine, N-propyldiallylamine, N-propyldioctylamine, N-propylbis(2-ethylhexyl)amine, N,N-diisopropylbutylamine, N,N-diisopropylallylamine, N,N-diisopropyloctylamine, N,N-diisopropyl(2-ethylhexyl)amine, N,N-diisopropylcyclohexylamine, N-isopropyldibutylamine, N-isopropyldiallylamine, N-isopropyldioctylamine, N-isopropylbis(2-ethylhexyl)amine, N,N-dibutylallylamine, N,N-dibutyloctylamine, N,N-dibutyl(2-ethylhexyl)amine, N,N-dibutylcyclohexylamine, N-butyldiallylamine, N-butyldioctylamine, N-butylbis(2-ethylhexyl)amine, N,N-diallyloctylamine, N,N-diallyl(2-ethylhexyl)amine, N,N-diallylcyclohexylamine, N-allyldioctylamine, N-allylbis(2-ethylhexyl)amine, N,N-dioctyl(2-ethylhexyl)amine, N,N-dioctylcyclohexylamine, N-octylbis(2-ethylhexyl)amine, N,N-bis(2-ethylhexyl)cyclohexylamine and the like, tertiary diamines such as N,N,N′,N′-tetramethyldiaminomethane, N,N,N′,N′-tetramethylethylenediamine, N,N,N′,N′-tetramethylpropanediamine, N,N,N′,N′-tetramethyltetramethylenediamine, N,N,N′,N′-tetramethylhexamethylenediamine and the like, tertiary polyamines such as pentamethyldiethylenetriamine and the like, N-substituted piperidines such as N-methylpiperidine, N-ethylpiperidine, N-methyl-2-pipecoline, N-methyl-3-pipecoline, N-methyl-4-pipecoline, N-methyl-4-piperidone, N-isobutyl-4-piperidone, N-benzyl-4-piperidone, 1,3-dimethyl-4-piperidone, dipiperidinomethane and the like, N-substituted piperazines such as 1,4-dimethylpiperazine and the like, N-substituted morpholines such as N-methylmorpholine, N-ethylmorpholine and the like, pyridines such as pyridine, 2-methylpyridine, 3-methylpyridine, 4-methylpyridine, 2-ethylpyridine, 2-propylpyridine, 2,6-dimethylpyridine, 2,4-dimethylpyridine, 3,4-dimethylpyridine, 3,5-dimethylpyridine, 2,4,6-trimethylpyridine, 2,3,5-trimethylpyridine, 4-dimethylaminopyridine, 4-pyrrolidinopyridine, 4-piperidinopyridine, 2-chloropyridine, 2-phenylpyridine, 2-benzylpyridine, 4-phenylpropylpyridine, quinoline, 3-methylquinoline, 2,3-cyclocyclopentenopyridine, 1,3-di(4-pyridyl)propane and the like, pyrazines such as 2-methylpyrazine, 2,5-dimethylpyrazine and the like, pyrrolidines such as N-methylpyrrolidine, N-ethylpyrrolidine and the like, pyrimidine, 2-methylpyrimidine, 1,2-dimethyl-1,4,5,6-tetrahydropyrimidine, 1,5-diazabicyclo[4.3.0]non-5-ene and the like.

An amount of the base to be used is not particularly limited, but is preferably not less than 1 mole based on 1 mole of a halogeno group in α-haloether.

An amount of a halogeno group in α-haloether can be obtained by measuring an acid value of the crude product obtained in the step (1).

A reaction temperature is not particularly limited, but is preferably 30 to 200° C., more preferably 40 to 160° C.

After completion of the reaction, purification by the known procedure such as filtration, washing with water, distillation and the like can afford polyfunctional alkenyl ether represented by the general formula (I).

### (C) Photoacid Generator

Examples of the photoacid generator include sulfonium salt, iodonium salt, sulfonyldiazomethane, N-sulfonyloximino or imido-type acid generator, benzoinsulfonate-type photoacid generator, pyrogalloltrisulfonate-type photoacid generator, nitrobenzylsulfonate-type photoacid generator, sulfone-type photoacid generator, glyoxime derivative-type photoacid generator and the like and, inter alia, sulfonium salt, iodonium salt, sulfonyldiazomethane, N-sulfonyloximino or imido-type acid generator is preferable.

The sulfonium salt is a salt of a sulfonium cation and sulfonate. Examples of the sulfonium cation include triphenylsulfonium, (4-tert-butoxyphenyl)diphenylsulfonium, bis(4-tert-butoxyphenyl)phenylsulfonium, tris(4-tert-butoxyphenyl)sulfonium, (3-tert-butoxyphenyl)diphenylsulfonium, bis(3-tert-butoxyphenyl)phenylsulfonium, tris(3-tert-butoxyphenyl)sulfonium, (3,4-di-tert-butoxyphenyl)diphenylsulfonium, bis(3,4-di-tert-butoxyphenyl)phenylsulfonium, tris(3,4-di-tert-butoxyphenyl)sulfonium, diphenyl(4-thiophenoxyphenyl)sulfonium, (4-tert-butoxycarbonylmethyloxyphenyl)diphenylsulfonium, tris(4-tert-butoxycarbonylmethyloxyphenyl)sulfonium, (4-tert-butoxyphenyl)bis(4-dimethylaminophenyl)sulfonium, tris(4-dimethylaminophenyl)sulfonium, 2-naphthyldiphenylsulfonium, dimethyl-2-naphthylsulfonium, 4-hydroxyphenyldimethylsulfonium, 4-methoxyphenyldimethylsulfonium, trimethylsulfonium, 2-oxocyclohexylcyclohexylmethylsulfonium, trinaphthylsulfonium, tribenzylsulfonium and the like. Examples of the sulfonate include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, 4-(4-toluenesulfonyloxy)benzenesulfonate, naphthalenesulfonate, camphorsulfonate, octanesulfonate, dodecylbenzenesulfonate, butanesulfonate, methanesulfonate and the like.

The iodonium salt is a salt of an iodonium cation and sulfonate. Examples of the iodonium cation include allyliodonium cations such as diphenyliodonium, bis(4-tert-butylphenyl)iodonium, (4-tert-butoxyphenyl)phenyliodonium, (4-methoxyphenyl)phenyliodonium and the like. Examples of the sulfonate include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, 4-(4-toluenesulfonyloxy)benzenesulfonate, naphthalenesulfonate, camphorsulfonate, octanesulfonate, dodecylbenzenesulfonate, butanesulfonate, methanesulfonate and the like.

Examples of the sulfonyldiazomethane include bissulfonyldiazomethanes such as bis(ethylsulfonyl)diazomethane, bis(1-methylpropylsulfonyl)diazomethane, bis(2-methylpropylsulfonyl)diazomethane, bis(1,1-dimethylethylsulfonyl)diazomethane, bis(cyclohexylsulfonyl)diazomethane, bis(perfluoroisopropylsulfonyl)diazomethane, bis(phenylsulfonyl)diazomethane, bis(4-methylphenylsulfonyl)diazomethane, bis(2,4-dimethylphenylsulfonyl)diazomethane, bis(2-naphthylsulfonyl)diazomethane, (4-methylphenyl)sulfonylbenzoyldiazomethane, (tert-butylcarbonyl)-(4-methylphenylsulfonyl)diazomethane, (2-naphthylsulfonyl)benzoyldiazomethane, (4-methylphenylsulfonyl)-(2-naphthoyl)diazomethane, methylsulfonylbenzoyldiazomethane, (tert-butoxy carbonyl)-(4-methylphenylsulfonyl)diazomethane and the like, and sulfonylcarbonyldiazomethane and the like.

Examples of the N-sulfonyloximino-type photoacid generator include [5-(4-methylphenylsulfonyloximino)-5H-thiophen-2-ylidene]-(2-methylphenyl)acetonitrile, (5-propylsulfonyloximino-5H-thiophen-2-ylidene)-(2-methylphenyl)acetonitrile, (5-camphorsulfonyloximino-5H-thiophen-2-ylidene)-(2-methylphenyl)acetonitrile, 2-(9-camphorsulfonyloximino)-2-(4-methoxyphenyl)acetonitrile, 2-(4-methylphenylsulfonyloximino)-2-phenylacetonitrile, 2-(4-methylphenylsulfonyloximino)-2-(4-methoxyphenyl)acetonitrile (PAI-101, manufactured by Midori Kagaku Co., Ltd.) and the like.

Examples of the N-sulfonyloxyimido-type photoacid generator include compounds consisting of a combination of an imido skeleton such as succinimide, naphthalenedicarboxylic imide, phthalic imide, cyclohexyldicarboxylic imide, 5-norbornene-2,3-dicarboxylic imide, 7-oxabicyclo[2.2.1]-5-heptene-2,3-dicarboxylic imide and the like, and trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesultonate, dodecylbenzenesulfonate, butanesulfonate, methanesulfonate or the like.

Examples of the benzoinsulfonate-type photoacid generator include benzointosylate, benzoinmesylate, benzoinbutanesulfonate and the like.

Examples of the pyrogalloltrisulfonate-type photoacid generator include compounds in which all of hydroxyl groups of pyrogallol, phloroglycine, catechol, resorcinol, hydroquinone or the like are substituted with trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, methanesulfonate or the like.

Examples of the nltrobenzylsulfonate-type photoacid generator include 2,4-dinitrobenzylsulfonate, 2-nitrobenzylsulfonate, 2,6-dinitrobenzylsulfonate and the like, and specific examples of the sulfonate include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, methanesulfonate and the like. Alternatively, compounds in which a nitro group on a benzyl side is substituted with a trifluoromethyl group can be used similarly.

Examples of the sulfone-type photoacid generator include bis(phenylsulfonyl)methane, bis(4-methylphenylsulfonyl)methane, bis(2-naphthylsulfonyl)methane, 2,2-bis(phenylsulfonyl)propane, 2,2-bis(4-methylphenylsulfonyl)propane, 2,2-bis(2-naphthylsulfonyl)propane, 2-methyl-2-(p-toluenesulfonyl)propiophenone, 2-(cyclohexylcarbonyl)-2-(p-toluenesulfonyl)propane, 2,4-dimethyl-2-(p-toluenesulfonyl)pentane-3-one and the like.

Examples of the glyoxime derivative-type photoacid generator include bis-O-(p-toluenesulfonyl)-α-dime-hylglyoxime, bis-O-(p-toluenesulfol)-α-diphenylglyoxime, bis-O-(p-toluenesulfonyl)-α-dicyclohexylglyoxime, bis-C-(p-toluenesulfonyl)-2,3-pentanedioneglyoxime, bis-O-(p-toluenesulfonyl)-2-methyl-3,4-pentanedioneglyoxime, bis-O-(n-butanesulfonyl)-α-dimethylglyoxime, bis-O-(n-butanesulfonyl)-α-diphenylglyoxime, bis-O-(n-butanesulfonyl)-α-dicyclohexylglyoxime, bis-O-(n-butanesulfonyl)-2,3-pentanedioneglyoxime, bis-O-(n-butanesulfonyl)-2-methyl-3,4-pentanedioneglyoxime, bis-O-(methanesulfonyl)-α-dimethylglyoxime, bis-O-(trifluoromethanesulfonyl)-α-dimethylglyoxime, bis-O-(1,1,1-trifluoroethanesulfonyl)-α-dimethylglyoxime, bis-C-(tert-butanesulfonyl)-α-dimethylglyoxime, bis-O-(perfluorooctanesulfonyl)-α-dimethylglyoxime, bis-O-(cyclohexylsulfonyl)-α-dimethylglyoxime, bis-O-(benzenesulfonyl)-α-dimethylglyoxime, bis-O-(p-fluorobenzenesulfonyl)-α-dimethylglyoxime, bis-O-(p-tert-butylbenzenesulfonyl)-α-dimethylglyoxime, bis-O-(xylenesulfonyl)-α-dimethylglyoxime, bis-O-(camphorsulfonyl)-α-dimethylglyoxime and the like.

Photoacid generators may be used alone, or by mixing two or more kinds.

An amount of the photoacid generator in the photoresist composition of the present invention is not particularly limited, but is preferably 0.001 to 50 parts by weight, more preferably 0.01 to 30 parts by weight, further preferably 0.1 to 10 parts by weight based on 100 parts by weight of the polymer containing a carboxyl group or a hydroxyl group.

The photoresist composition of the present invention may further contain a photosensitizer, or coloring matters such as anthracenes, anthraquinones, coumarines, and pyromethenes, if necessary.

The photoresist composition of the present invention may contain an organic solvents, if necessary.

Examples of the organic solvent include ketones such as acetone, methyl ethyl ketone, methyl isobutyl ketone, methyl amyl ketone, methyl isoamyl ketone, cyclohexanone, cyclopentanone and the like, glycol ethers such as propylene glycol monomethylether, propylene glycol monoethylether, ethylene glycol monomethylether, ethylene glycol monoethylether, diethylene glycol monomethylether, diethylene glycol monoethylether, propylene glycol dimethylether, ethylene glycol dimethylether, diethylene glycol dimethylether, 3-methoxybutanol, 3-methyl-3-methoxybutanol and the like, glycol ether acetates such as propylene glycol monomethyl ether acetate, propylene glycol monoethylether acetate, ethylene glycol monomethyl ether acetate, ethylene glycol monoethyl ether acetate and the like, esters such as butyl acetate, amyl acetate, cyclohexyl acetate, tert-butyl acetate, methyl methoxypropionate, ethyl ethoxypropionate, methyl acetoacetate, ethyl acetoacetate, methyl lactate, ethyl lactate, propyl lactate, methyl pyruvate, ethyl pyruvate, propyl pyruvate, tert-butyl propionate, methyl β-methoxyisobutyrate and the like, hydrocarbons such as hexane, toluene, xylene and the like, cyclic ethers such as dioxane, tetrahydrofuran, γ-butyrolactone, N,N-dimethylformamide, N-methylpyrolidone, dimethyl sulfoxide and the like.

The organic solvents may be used alone, or by mixing two or more kinds.

By inclusion of the organic solvent in the photoresist composition of the present invention, a viscosity of the photoresist composition of the present invention can be adjusted.

An amount of the organic solvent in the photoresist composition of the present invention is not particularly limited, but is preferably 100 to 400 parts by weight, more preferably 200 to 3000 parts by weight, further preferably 300 to 2000 parts by weight base on 100 parts by weight of the polymer containing a carboxyl group or a hydroxyl group.

And, the photoresist composition of the present invention may contain a basic compound, if necessary.

Examples of the basic compounds include primary secondary or tertiary aliphatic amines, aromatic amines, heterocyclic amines, nitrogen-containing compounds having a carboxyl group, nitrogen-containing compounds having a sulfonyl group, nitrogen-containing compounds having a hydroxyl group, nitrogen-containing compounds having a hydroxyphenyl group, amide derivatives, imide derivatives and the like. The basic compounds may be used alone, or by mixing two or more kinds.

An amount of the basic compound in the photoresist composition of the present invention is not particularly limited, but is preferably 0.001 to 10 parts by weight, more preferably, 0.01 to 5 parts by weight based on 100 parts by weight of the polymer containing a carboxyl group or a hydroxyl group.

By inclusion of the basic compound in the photoresist composition of the present invention, a diffusion rate of the acid in the resist composition is suppressed, a light exposure allowance degree and a pattern profile are improved, thereby, influence on the substrate and the environment on a resist membrane can be reduced.

And, by inclusion of the basic compound in the photoresist composition of the present invention, storage stability of the photoresist composition can be improved.

Further, the photoresist composition of the present invention may contain a surfactant, if necessary.

Examples of the surfactant include nonionic surfactants such as polyoxyethylene alkyl allyl ethers, polyoxyethylene polyoxypropylene block copolymers, sorbitan fatty acid esters, and polyoxyethylene sorbitan fatty acid ester, fluorine-based surfactants, organosiloxane polymers and the like. Surfactants may be used alone, or by mixing two or more kinds.

By inclusion of the surfactant in the photoresist composition of the present invention, the coating property of the photoresist composition can be improved.

In addition, the photoresist composition of the present invention may contain a dissolution adjusting agent such as a phenol compound, a ultraviolet absorbing agent, a storage stabilizer, an anti-foaming agent and the like, if necessary.

### (Method of Preparing Photoresist Composition of the Present Invention)

The photoresist composition of the present invention can be prepared as a solution by mixing (A) a polymer containing a carboxyl group or a hydroxyl group, (B) a polyfunctional alkenyl ether represented by the general formula (I), (C) a photoacid generator and, if necessary, an additive such as a photosensitizer, an organic solvent, a basic compound, a surfactant, a dissolution adjusting agent, a ultraviolet absorbing agent, a storage stabilizer, an anti-foaming agent and the like. An order of mixing, a method of mixing and the like are not particularly limited.

Alternatively, the photoresist composition of the present invention may be a dry film. The dry film can be made, for example, by coating the solution on a support such as a metal and polyethylene terephthalate, drying this, and peeling a film from the support. Alternatively, when the support is a film of polyethylene terephthalate or the like, it may be used as it is as the photoresist composition of the present invention.

Examples of the method of coating the photoresist composition of the present invention on a support include spin coating, roll coating, flow coating, dipping coating, spray coating, doctor coating and the like.

A thickness of a coated film can be set depending on utility, and is preferably 0.05 to 200 μm, more preferably 0.1 to 100 μm.

Examples of the film used as the support include polyethylene terephthalate, polypropylene, polyethylene, polyester, polyvinyl alcohol and the like.

When the photoresist composition of the present invention is a dry film, if necessary, the resist composition may be covered with a protective film for the purpose of protecting the resist composition from a flaw, a dust, a medicament or the like. Examples of the protective film include a polyethylene film, a polypropylene film and the like, and a film having a smaller force of adhering with the photoresist composition than that of the support is preferable.

Alternatively, a peeling layer may be provided between the protective film and the photoresist composition.

The dry film may be wound into a roll.

### (Method of Forming Pattern of the Present Invention)

The method of forming a pattern of the present invention comprises a step of coating a photoresist composition of the present invention on a substrate, a step of heating the substrate, a step of exposing a coated film on the substrate to radiation or electron beam, a step of heating the substrate after exposure, and a step of developing the substrate using an alkaline developer.

The substrate is not particularly limited, but examples include an aluminum plate, a copper foil laminate plate, a glass plate, a silicon wafer and the like.

Examples of the method of coating the photoresist composition of the present invention on a substrate, when the photoresist composition is a solution, include the known method such as spin coating, roll coating, flow coating, dipping coating, spray coating, doctor coating and the like. A thickness of a coated film can be set depending on utility, and is preferably 0.05 to 200 μm, more preferably 0.1 to 100 μm.

When the photoresist composition of the present invention is a dry film, there is a method of coating, for example, laminating the photoresist composition so that the photoresist composition layer is directly contacted with a substrate when, there is a protective film, after the protective film is peeled. By adopting a temperature of 80 to 160° C. at lamination, the next step of heating treatment can be omitted.

After the photoresist composition of the present invention is coated on a substrate, the substrate is heated. When the photoresist composition is a solution, examples of the heating method include the known method such as heating with a hot plate, an oven or the like. By heating, an organic solvent is vaporized. And, Polymer (A) and Compound (I) are reacted to cross-link Polymer (A), thereby, a hydroxyl group or a carboxyl group of Polymer (A) is protected. As a result, the coated film becomes insoluble in an alkali developer. A heating temperature is preferably 80 to 160° C.

In the case where the photoresist composition is a dry film, when heating is performed at lamination, the present step can be omitted.

After heating, a coated film is irradiated with radiation using a photomask, a reduction-projection exposing machine, a direct display machine or the like. Examples of radiation include far ultraviolet-ray, visible light, near ultraviolet-ray such as g-ray, h-ray, i-ray and the like, KrF excimer laser, ArF excimer laser, DUV (far ultraviolet-ray), EUV (extremely ultraviolet-ray), electron beam, X-ray and the like. At a part irradiated with radiation, a photoacid generator is degraded to generate an acid.

After irradiation, the substrate is heated. Examples of the heating method include those used in heating after coating. By heating, a hydroxyl group or a carboxyl group is regenerated. A heating temperature is preferably 80 to 160° C.

After heating, when a dry film is used, the support is removed, or when a dry film is not used, the film as it is developed using an alkaline developer to obtain a positive-type resist pattern. Examples of the developing method include the known method such as an immersing method, a paddling method, a spraying method and the like. Examples of the alkaline developer include aqueous alkaline solutions in which a basic substance such as sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, choline, pyrrole, piperidine, 1,8-diazabicyclo[5.4.0]-7-undecene, 1,5-diazabicyclo[4.3.0]-5-nonane and the like is dissolved. Basic substances may be used alone, or by mixing two or more kinds. Alternatively, the developer may be used by adding a water-soluble organic solvent, for example, alcohols such as methanol, ethanol and the like, and a surfactant at a suitable amount.

After development, if necessary, the substrate may be washed with water and/or dried by heating.

The photoresist composition of the present invention is a photoresist composition having a nature that a difference in solubility in an alkaline developer of a light-exposed part and a light-unexposed part is great, a sensitivity and a resolution are high, change in a pattern shape is small, etching resistance is excellent, a scum is small, and storage stability is excellent.

The present invention will be explained more specifically below by way of Synthesis Examples, Test Examples, Examples, and Comparative Examples.

A structure of compounds in Examples was determined by ¹H-NMR spectrum (400 MHz, a measuring instrument: JEOL Ltd. GSX-400, measuring solvent: heavy chloroform).

A weicht average molecular weight was measured by gel permeation chromatography (GPC) under the following conditions.

### (Gpc Analysis Conditions)

Instrument: HLC-8120GPC (manufactured by TOSOH CORPORATION)
Column: TSKgel SuperHM-M (manufactured by TOSOH CORPORATION)
Mobile phase: tetrahydrofuran (flow rate 0.5 ml/min)
Column oven: 40° C.
Detector: RI[RI-8000 (manufactured by TOSOH CORPORATION)]

An acid value was obtained by neutralization titration with a 0.1M aqueous KOH alcohol solution.

Differential thermal balance analysis (DSC) was performed using, TG/TDA6200 manufactured by Seiko Instruments Inc. under the condition of elevating a temperature from 40° C. to 400° C. at 10° C./min under the nitrogen atmosphere.

A film thickness was measured using an optical interference-type thicknessmeter (manufactured by Nanospec)

### SYNTHESIS EXAMPLE 1

### Synthesis of Polymer Containing Carboxyl Group

A flask equipped with an addition device, a stirring device, a thermometer, a condenser and a nitrogen gas introducing tube was charged with 100 g of propylene glycol monomethyl ether acetate, and heated to 100° C., and a solution in which 12.3 g of methacrylic acid, 57.7 g of methyl methacrylate, 30.0 g of butyl methacrylate and 15.0 g of azobisisobutyronitrile (AIBN) had been uniformly dissolved was added dropwise from the addition device over 4 hours, while stirring under the nitrogen atmosphere. After completion of addition, a mixed solution of AIBN/propylene glycol monomethyl acetate=0.2 g/0.3 g was added two times every 30 minutes, and this was aged at 100° C. for 2 hours to stop a polymerization reaction. The resulting resin solution was purified by re-precipitation with hexane to obtain 80 g of a white solid. A weight average molecular weight of the solid was 3,600 and an acid value was 80. This solid was designated as resin 1.

### SYNTHESIS EXAMPLE 2

### Synthesis of Polymer Containing Hydroxyl Group

A separable flask equipped with a stirrer, a condenser and a thermometer was charged with 123.2 g of m-cresol, 52.2 g of 3,5-xylene, 130.3 g of a 37 wt % aqueous formaldehyde solution and 0.731 g of oxalic acid-dihydrate, and a mixture was stirred for 40 minutes while an inner temperature was retained at 100° C. Thereafter, 27.9 g of m-cresol and 13.1 g of 3.5-xylenol were added, and the mixture was further stirred for 100 minutes. Thereafter, an inner temperature was elevated to 180° C., and a pressure of the interior was reduced to 30 to 40 mmHg to remove a low boiling fraction. After allowing to cool to room temperature, the solid was recovered. This solid was dissolved in ethylcellosolve acetate so that a solid matter became 20% be weight, methanol at an amount which was 2-fold a weight of a resin solution, and an equal amount of water were added, and the mixture was stirred and allowed to stand. The solution separated into two layers. The lower layer was taken out, concentrated, dehydrated and dried to obtain 50 g of a brown solid. A weight average molecular weight of the solid was 3,000. This solid was designated as resin P-2.

### SYNTHESIS EXAMPLE 3

### Synthesis of Polymer Containing Hydroxyl Group

In 30 g of tetrahydrofuran was dissolved log of commercially available poly-p-hydroxystyrene (weight average molecular weight 19,000; manufactured by Aldrich), and purified by re-precipitation with hexane to obtain 8 g of a white solid. This solid was designated as resin P-3.

### EXAMPLE 1

### Synthesis of Ethylene Glycol Diisobutenyl Ether

In 200 ml of toluene were dissolved 62.0 g of isobutylaldehyde and 24.3 g of ethylene glycol, and 29.0 g of a HCl gas was blown therein while a reaction temperature was retained at 10 to 20° C. The reaction solution was allowed to stand, and the lower layer was removed. Triethylamine at an amount of 87.1 g was added at once, and the mixture was stirred at 100° C. for 6 hours. After cooled to room temperature, the reaction solution was washed with 230 g of a 15% aqueous NaOH solution once. The resulting solution was distilled under reduced pressure to obtain 28.4 g of a colorless transparent liquid. ¹H-NMR spectrum confirmed that the fraction was ethylene glycoldiisobutenyl ether. This was designated as (E-1).

¹H-NMR δ 5.82 (2H, m), 3.82 (4H, s), 1.61-1.59 (6H, m), 1.54-1.52 (6H, m)

### EXAMPLE 2

### Synthesis of Diethylene Glycol Diisobutenyl Ether

In 200 ml of toluene were dissolved 56.6 g of isobutylaldehyde and 41.6 g diethylene glycol, and 29.0 g of a HCl gas was blown therein while a reaction temperature was retained of 10 to 20° C., a reaction solution was allowed to stand, and the lower layer was removed. Triethylamine at an amount of 87.4 g was added at once and the mixture was stirred at 100° C. for 5 hours. After cooled to room temperature, the solution was washed with 230 g of a 15% aqueous NaOH solution once. The resulting solution was distilled under reduced pressure to obtain 54.1 g of a colorless transparent liquid. ¹H-NMR spectrum confirmed the fraction was diethylene glycol diisobutenyl ether. This was designated as (E-2).

¹H-NMR δ 5.83-5.82 (2H, m), 3.82-3.80 (4H, m), 3.70-3.67 (4H, m), 1.61 (6H, m), 1.54 (6H, m)

### EXAMPLE 3

### Synthesis of Triethylene Glycol Diisobutenyl Ether

In 150 ml of toluene were dissolved 70.3 g of isobutylaldehyde and 69.5 g of triethylene glycol, and 47.2 g of a HCl gas was blown therein while a reaction temperature was retained at to 20° C. The reaction solution was allowed to stand, and the lower layer was removed. Triethylamine at an amount of 108.6 g was added at once, and the mixture was stirred at 100° C. for 5 hours. After cooled to room temperature, the precipitated solid was removed by filtration. The resulting solution was distilled under reduced pressure to obtain 33.5 g of a colorless transparent liquid. ¹H-NMR spectrum confirmed that the fraction was triethylene glycol diisobutenyl ether. This was designated as (E-3).

¹H-NMR δ 5.83-5.82 (2H, m), 3.82-3.80 (4H, m), 3.68-3.66 (8H, m), 1.60 (6H, m), 1.54-1.53 (6H, m)

### EXAMPLE 4

### Synthesis of 1,4-butanediol Diisobutenyl Ether

In 100 ml of toluene were dissolved 52.6 g of isobutylaldehyde and 32.9 g of 1,4-butanediol, and 31.0 g of a HCl gas was blown therein while a reaction temperature was retained at 10 to 20° C. The reaction solution was allowed to stand, and the lower layer was removed. Triethylamine at an amount of 88.6 g was added at once, and the mixture was stirred at 110° C. for 5 hours. After cooled to room temperature, the solution was washed with 200 g of water two times. The resulting solution was distilled under reduced pressure to obtain 46.2 g of a colorless transparent liquid.

¹H-NMR spectrum confirmed that the fraction was 1,4-butanediol diisobutenyl ether. This was designated as E-4.

¹H-NMR δ 5.79-5.77 (2H, m), 3.70-3.67 (4H, m), 1.70-1.67 (4H, m), 1.60 (6H, m), 1.54 (6H, d, J=0.7)

### EXAMPLE 5

### Synthesis of 1,4-bis(hydroxymethyl)cyclohexane diisobutenyl Ether

In 100 ml of toluene were dissolved 49.5 g of isobutylaldehyde and 49.2 g of 1,4-bis(hydroxymethyl)cyclohexane, and 31.0 g of a HCl gas was blown therein while a reaction temperature was retained at 10 to 20° C. The reaction solution was allowed to stand, and the lower layer was removed. Triethylamine at an amount of 76.5 g was added at once, and the mixture was stirred at 110° C. for 9 hours. After cooled to room temperature, this was washed with 200 g of a 15% aqueous NaOH solution once, the resulting solution was distilled under reduced pressure to obtain 55.2 g of a colorless transparent liquid. ¹H-NMR spectrum confirmed that the fraction was 1,4-bis(hydroxymethyl)cyclohexane diisobutenyl ether (mixture of two kinds of structural isomers). This was designated as E-5.

¹H-NMR δ 5.77 (2H, m), 3.55-3.46 (4H, m), 1.83-1.38 (7H, m), 1.60 (6H, s), 1.53 (6H, m), 1.00-0.96 (3H, m)

### EXAMPLE 6

According to Table 1, a resin, a polyfunctional alkenyl ether, a photoacid generator and an organic solvent were mixed. The resulting solution was filtered with a 0.2 μm membrane filter to obtain a composition 1.

### EXAMPLE 7

According to Table 1, a resin, a polyfunctional alkenyl ether, a photoacid generator and an organic solvent were mixed. The resulting solution was filtered with a 0.2 μm membrane filter to obtain a composition 2.

### EXAMPLE 8

According to Table 1, a resin, a polyfunctional alkenyl ether, a photoacid generator and an organic solvent were mixed. The resulting solution was filtered with a 0.2 μm membrane filter to obtain a composition 3.

### EXAMPLE 9

According to Table 1, a resin, a polyfunctional alkenyl ether, a photoacid generator and an organic solvent were mixed. The resulting solution was filtered with a 0.2 μm membrane filter to obtain a composition 4.

### EXAMPLE 10

According to Table 1, a resin, a polyfunctional alkenyl ether, a photoacid generator and an organic solvent were mixed. The resulting solution was filtered with a 0.2 μm membrane filter to obtain a composition 5.

### EXAMPLE 11

According to Table 1, a resin, a polyfunctional alkenyl ether, a photoacid generator and an organic solvent were mixed. The resulting solution was filtered with a 0.2 μm membrane filter to obtain a composition 6.

### EXAMPLE 12

According to Table 1, a resin, a polyfunctional alkenyl ether, a photoacid generator and an organic solvent were mixed. The resulting solution was filtered with a 0.2 μm membrane filter to obtain a composition 7.

### COMPARATIVE EXAMPLE 1

According to Table 1 and the same manner as that of Example 5, 1,4-butanediol divinyl ether (V-1) was used in place of the polyfunctional alkenyl ether to obtain a composition 8.

TABLE 1

| | | composition | composition | composition | composition | composition | composition | composition | composition |
|---|---|---|---|---|---|---|---|---|---|
| | | 1 | 2 | 3 | 4 | 5 | 6 | 7 | 8 |
| Resin | P-1 | 20 | | | 20 | 20 | 20 | 20 | 20 |
| | P-2 | | 20 | | | | | | |
| | P-3 | | | 20 | | | | | |
| Poly- | E-1 | | | | 4 | | | | |
| functional | E-2 | | | | | 4 | | | |
| alkyl | E-3 | | | | | | 4 | | |
| ether | E-4 | 4 | 4 | 4 | | | | | |
| | E-5 | | | | | | | 4 | |
| | V-1 | | | | | | | | 4 |

| | | | | | | | | |
|---|---|---|---|---|---|---|---|---|
| Photoacid | 1 | 1 | 1 | 1 | 1 | 1 | 1 | 1 |
| generator | | | | | | | | |
| Organic solvent | 57 | 57 | 57 | 57 | 57 | 57 | 57 | 57 |

As the photoacid generator, PAI-101 (manufactured by Midori Kagaku Co., Ltd.) was used. In addition, as the organic solvent, propylene glycol monomethyl ether acetate (manufactured by Kyowa Hakko Chemical Co., Ltd.) was used.

### TEST EXAMPLE

According to the following method, a pattern was formed, and a pattern shape, the presence or the absence of a scum, and storage stability of the photoresist composition were assessed.

### Pattern Formation

Each of compositions 1 to 7 was coated on a 4-inch silicon wafer with a spin coater (rotation number: 2000 rpm 60 seconds), and this was heated on a hot plate (100° C., 5 min). A film thickness was 2 μm. Then, this was exposed to i-ray at 20 mJ/cm² using a mask aligner (MA-4 manufactured by SUSS Micro Tec KK). After exposure, this was heated on a hot plate (120° C., 2 min), and developed with a 2.3% aqueous tetramethylammonium hydroxide solution (25° C., 120 seconds). Finally, washing with pure water afforded a 5 μm line and space pattern.

A pattern shape, and the presence or the absence of a scum were assessed by observing a front plane and a cross-section of the resulting pattern with a light microscope and a scanning electron microscope. The pattern shape was determined to be “∘” in the case of a rectangle, and determined to be “x” in the case of not a rectangle, for example, in the case of a round head. The presence or the absence of a scum was determined to be “presence” in the case of presence, and “absence” in the case of absence.

Storage stability of the photoresist was assessed by forming each pattern by the aforementioned method immediately after and three days after preparation of the photoresist composition and determining whether the same pattern was formed or not. The same pattern shape was determined to be “∘”, and the different pattern shape was determined to be “x”.

TABLE 2

| | | Pattern | | Pattern |
|---|---|---|---|---|
| | Composition | shape | Scum | identity |
| Example 6 | Composition 1 | ∘ | Absence | ∘ |
| Example 7 | Composition 2 | ∘ | Absence | ∘ |
| Example 8 | Composition 3 | ∘ | Absence | ∘ |
| Example 9 | Composition 4 | ∘ | Absence | ∘ |
| Example 10 | Composition 5 | ∘ | Absence | ∘ |
| Example 11 | Composition 6 | ∘ | Absence | ∘ |
| Example 12 | Composition 7 | ∘ | Absence | ∘ |
| Comparative | Composition 8 | x | Presence | x |
| example 1 | | | | |

From Table 2, it is seen that photoresist compositions obtained in Examples 6 to 12 have small change in a pattern shape, no scum, and excellent storage stability.

### INDUSTRIAL APPLICABILITY

According to the present invention, a photoresist composition in which change in a pattern shape is small, and a scum is small and the like can be provided.

1. A photoresist composition comprising (A) a polymer containing a carboxyl group or a hydroxyl group, (B) a polyfunctional alkenyl ether represented by the general formula (I):
[Chemical formula 8] 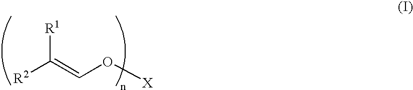
[wherein R¹ and R² may be the same as or different from each other and, respectively, represent substituted or unsubstituted alkyl, substituted or unsubstituted aryl or substituted or unsubstituted aralkyl, or R¹ and R² may form a substituted or unsubstituted alicyclic hydrocarbon ring together with a carbon atom adjacent thereto, X represents a substituted or unsubstituted alkane from which hydrogen atoms in the number of n are removed (the alkane includes alkane substituted with 1 to 2 aryls, and a part of carbon atoms of the alkane may be substituted with an oxygen atom or SO₂), a substituted or unsubstituted aromatic ring from which hydrogen atoms in the number of n are removed (the aromatic ring includes an aromatic ring substituted with alkyl), or a group represented by —{(CH₂—CH₂—O)ₘ—CH₂—CH₂}— (wherein m represents an integer of not less than 1) from which hydrogen atoms in the number of (n−2) are removed, and n represents an integer of not less than 2], and (C) a photoacid generator.

2. The photoresist composition according to claim 1, wherein the (A) polymer comprises a repetition unit represented by the general formula (II):
[Chemical formula 9] 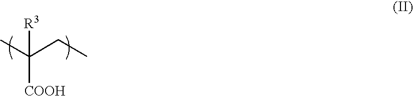
(wherein R³ represents a hydrogen atom or methyl), and has a weight average molecular weight of 1,000 to 100,000.

3. The photoresist composition according to claim 1, wherein the (A) polymer comprises a repetition unit represented by the general formula (III):
[Chemical formula 10] 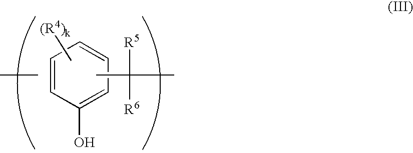
(wherein R⁴ represents a hydrogen atom, substituted or unsubstituted alkyl, substituted or unsubstituted aryl or substituted or unsubstituted aralkyl, k represents an integer of 1 to 3, R⁵ and R⁶ may be the same as or different from each other and, respectively, represent a hydrogen atom, substituted or unsubstituted alkyl, substituted or unsubstituted aryl or substituted or unsubstituted aralkyl), and has a weight average molecular weight of 1,000 to 100,000.

4. The photoresist composition according to claim 1, wherein the (A) polymer comprises a repetition unit represented by the general formula (IV);
[Chemical formula 11] 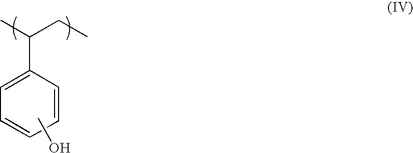
and has a weight average molecular weight of 1,000 to 100,000.

5. A method of forming a pattern comprising a step of coating the photoresist composition as defined in any one of claims 1 to 4 on a substrate, a step of heating the substrate, a step of exposing a coated film on the substrate to radiation, a step of heating the substrate after exposure, and a step of developing the substrate using an alkaline developer.

6. A polyfunctional alkenyl ether represented by the general formula (V):
[Chemical formula 12] 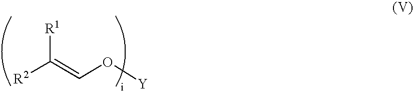
[wherein R¹ and R² are as defined above, Y represents a substituted or unsubstituted alkane from which hydrogen atoms in the number of i are removed (the alkane includes alkane substituted with 1 to 2 aryls, and a part of carbon atoms of the alkane may be substituted with an oxygen atoms or SO₂), a substituted or unsubstituted aromatic ring from which hydrogen atoms in the number of i are removed (the aromatic ring includes an aromatic ring substituted with alkyl), or a group represented by —{(CH₂—CH₂—O)ₘ—CH₂—CH₂}— (wherein m is as defined above) from which hydrogen atoms in the number of (i−2) are removed, and i represents an integer of 2 to 4].
